(19) United States
(12) Patent Application Publication
(10) Pub. No.: US 2026/0314387 A1
(43) Pub. Date: Oct. 8, 2026

(54) SEMICONDUCTOR DEVICE MANUFACTURING METHOD AND SEMICONDUCTOR DEVICE MANUFACTURING SYSTEM

(71) Applicant: Tokyo Electron Limited, Tokyo (JP)

(72) Inventors: Yuki KIKUCHI, Nirasaki-shi (JP); Takumi NISHINOBO, Albany, NY (US); Tushar Vijaykumar MESHRAM, Albany, NY (US); Takashi MATSUMOTO, Nirasaki-shi (JP); Masahito SUGIURA, Nirasaki-shi (JP); Tatsuya YAMAGUCHI, Nirasaki-shi (JP); Mel Forrest HAINEY, JR., Nirasaki-shi (JP)

(21) Appl. No.: 19/681,376

(22) Filed: May 19, 2026

Related U.S. Application Data
(63) Continuation of application No. PCT/JP2024/039542, filed on Nov. 7, 2024.

(30) Foreign Application Priority Data
Nov. 21, 2023 (JP) 2023-197076

(51) Int. Cl. H10W 20/46; H10P 14/60; H10P 14/69

(52) U.S. Cl. CPC H10W 20/46; H10P 14/6336; H10P 14/6902

(57) ABSTRACT

A semiconductor device manufacturing method includes: a) preparing, in a chamber, a substrate having a pattern including a plurality of metal-containing layers formed on an underlayer and a dielectric layer formed on each of the metal-containing layers; b) modifying sidewalls of the metal-containing layers by supplying a modifying gas into the chamber; c) generating plasma from a first processing gas including a carbon-containing gas in the chamber, and forming a graphene film on the sidewalls of the metal-containing layers by using the generated plasma; d) embedding a thermally decomposable organic film in a groove formed by adjacent metal-containing layers; e) forming a sealing film on the organic film embedded in the groove; and f) forming an air gap between the groove and the sealing film, by heating the substrate to thermally decompose the organic film and detaching the organic film via the sealing film.

### CROSS-REFERENCE TO RELATED APPLICATIONS

The application is a Bypass Continuation Application of PCT International Application No. PCT/JP2024/039542, filed on Nov. 7, 2024 and designating the United States, the international application being based upon and claiming the benefit of priority from Japanese Patent Application No. 2023-197076, filed on Nov. 21, 2023, the entire contents of which are incorporated herein by reference.

### TECHNICAL FIELD

The present disclosure relates to a semiconductor device manufacturing method and a semiconductor device manufacturing system.

### BACKGROUND

For example, Patent Document 1 discloses a semiconductor device manufacturing method which includes a first deposition step, a second deposition step, and a detachment step. In the first deposition step, a thermally decomposable organic material is deposited on a substrate having a recess formed therein. In the second deposition step, a silicon nitride film is deposited on the organic material. In the detachment step, the organic material is thermally decomposed by heating the substrate to a predetermined temperature, and the organic material below the silicon nitride film is detached via the silicon nitride film to form an air gap.

### PRIOR ART DOCUMENT

### PATENT DOCUMENT

Patent Document 1: Japanese Patent Laid-open Publication No. 2021-108353

### SUMMARY

A semiconductor device manufacturing method according to an aspect of the present disclosure includes: a) preparing, in a chamber, a substrate having a pattern including a plurality of metal-containing layers formed on an underlayer and a dielectric layer formed on each of the metal-containing layers; b) modifying sidewalls of the metal-containing layers by supplying a modifying gas into the chamber; c) generating plasma from a first processing gas including a carbon-containing gas in the chamber, and forming a graphene film on the sidewalls of the metal-containing layers by using the generated plasma; d) embedding a thermally decomposable organic film in a groove formed by adjacent metal-containing layers; e) forming a sealing film on the organic film embedded in the groove; and f) forming an air gap between the groove and the sealing film, by heating the substrate to thermally decompose the organic film and detaching the organic film via the sealing film.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a system configuration diagram illustrating an example of a manufacturing system according to an embodiment of the present disclosure.

FIG. 2 is a diagram illustrating an example of a film forming apparatus.

FIG. 3 is a diagram schematically illustrating an example of a ceiling wall.

FIG. 4 is a diagram illustrating an example of a film forming apparatus.

FIG. 5 is a diagram illustrating an example of a plasma processing apparatus.

FIG. 6 is a diagram illustrating an example of a heating apparatus.

FIG. 7 is a flowchart illustrating an example of a semiconductor device manufacturing method according to a first embodiment.

FIG. 8A is a diagram illustrating an example of a semiconductor device manufacturing process according to the first embodiment.

FIG. 8B is a diagram illustrating an example of the semiconductor device manufacturing process according to the first embodiment.

FIG. 8C is a diagram illustrating an example of the semiconductor device manufacturing process according to the first embodiment.

FIG. 8D is a diagram illustrating an example of the semiconductor device manufacturing process according to the first embodiment.

FIG. 8E is a diagram illustrating an example of the semiconductor device manufacturing process according to the first embodiment.

FIG. 8F is a diagram illustrating an example of the semiconductor device manufacturing process according to the first embodiment.

FIG. 8G is a diagram illustrating an example of the semiconductor device manufacturing process according to the first embodiment.

FIG. 9 is a diagram illustrating an example of a state of an air gap for each thickness of a sealing film.

FIG. 10A is a diagram illustrating an example of a resistance of a metal-containing layer in a comparative example.

FIG. 10B is a diagram illustrating an example of a reduction rate of the resistance in the comparative example.

FIG. 11A is a diagram illustrating an example of a resistance of a metal-containing layer in the first embodiment.

FIG. 11B is a diagram illustrating an example of a reduction rate of the resistance in the first embodiment.

FIG. 12A is a diagram illustrating an example of a capacitance between metal-containing layers in the comparative example.

FIG. 12B is a diagram illustrating an example of a capacitance between metal-containing layers in the first embodiment.

FIG. 13 is a diagram illustrating an example of a leakage current in the first embodiment.

FIG. 14 is a flowchart illustrating an example of a semiconductor device manufacturing method according to a second embodiment.

FIG. 15 is a diagram illustrating an example of a semiconductor device manufacturing process according to the second embodiment.

FIG. 16 is a diagram illustrating an example of a leakage current in the second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a semiconductor device manufacturing method and a semiconductor device manufacturing system disclosed herein will be described in detail with reference to the drawings. The semiconductor device manufacturing method and the semiconductor device manufacturing system disclosed herein are not limited to the following embodiments.

As semiconductor devices have become more functional and denser in recent years, there is a tendency that internal wiring becomes thinner and a wiring resistance increases. Further, as a density of semiconductor devices has increased, there is a tendency that spacing between internal wirings becomes narrower and a wiring capacitance increases. When the wiring resistance and the wiring capacitance increase, signal delay flowing through the wiring increases, and signal quality deteriorates. Therefore, there is a demand for reducing the wiring resistance and the wiring capacitance of the wiring inside semiconductor devices.

Therefore, the present disclosure provides a technique capable of manufacturing a semiconductor device with low signal delay.

### First Embodiment

### Configuration Example of Manufacturing System 10

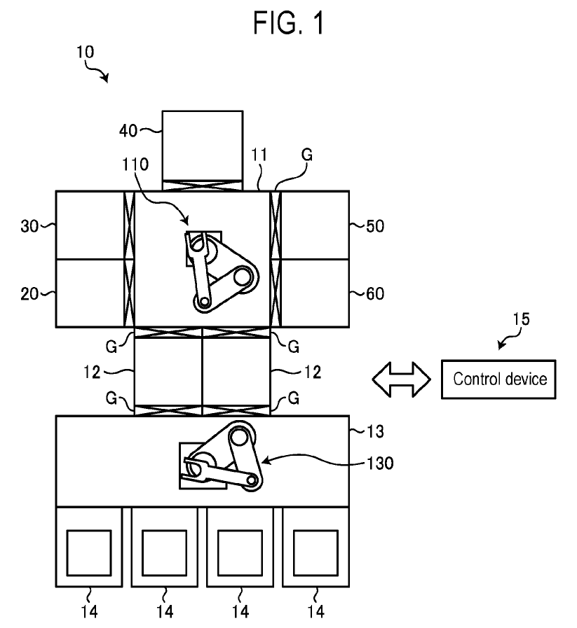

FIG. 1 is a system configuration diagram showing an example of a manufacturing system 10 according to an embodiment of the present disclosure. The manufacturing system 10 includes a VTM (Vacuum Transfer Module) 11, a plurality of LLMs (Load Lock Modules) 12, and an EFEM (Equipment Front End Module) 13. A film forming apparatus 20, a film forming apparatus 30, a plasma processing apparatus 40, a film forming apparatus 50, and a heating apparatus 60 are connected to sidewalls of the VTM 11 via gate valves G. In the example shown in FIG. 1, one film forming apparatus 20, one film forming apparatus 30, one plasma processing apparatus 40, one film forming apparatus 50, and one heating apparatus 60 are connected to the VTM 11. However, the disclosed technique is not limited thereto. As another example, at least one of the film forming apparatus 20, the film forming apparatus 30, the plasma processing apparatus 40, the film forming apparatus 50, or the heating apparatus 60 may be connected to the VTM 11 in plural.

The film forming apparatus 20 forms a graphene film on a sidewall of each metal-containing layer in a substrate W having a pattern, which includes a plurality of metal-containing layers formed on an underlayer and a dielectric layer formed on each of the metal-containing layers. The film forming apparatus 20 is an example of a first processing apparatus.

The film forming apparatus 30 embeds a thermally decomposable organic film in a groove formed by adjacent metal-containing layers in the substrate W. The film forming apparatus 30 is an example of a second processing apparatus.

The plasma processing apparatus 40 removes unnecessary organic films formed on the dielectric layer.

The film forming apparatus 50 forms a sealing film on the organic film embedded in the groove of the substrate W. The film forming apparatus 50 is an example of a third processing apparatus.

The heating apparatus 60 heats the substrate W to thermally decompose the organic film, and detaches the organic film via the sealing film, thereby forming an air gap between the groove and the sealing film. The heating apparatus 60 is an example of a fourth processing apparatus.

The plurality of LLMs 12 are connected to another side wall of the VTM 11 via gate valves G. In the example of FIG. 1, two LLMs 12 are connected to the VTM 11, but the number of LLMs 12 connected to the VTM 11 may be more than two, or may be one.

A transfer robot 110 is disposed in the VTM 11. The transfer robot 110 transfers the substrate W among the film forming apparatus 20, the film forming apparatus 30, the plasma processing apparatus 40, the film forming apparatus 50, the heating apparatus 60, and the LLMs 12. The interior of the VTM 11 is maintained at a predetermined pressure that is lower than atmospheric pressure.

One sidewall of each of the LLMs 12 is connected to the VTM 11 via a gate valve G, and another sidewall of each of the LLMs 12 is connected to the EFEM 13 via a gate valve G. When the substrate W is loaded from the EFEM 13 into the LLM 12 via the gate valve G, the gate valve G is closed and a pressure inside the LLM 12 is reduced to a pressure approximately equal to a pressure inside the VTM 11. Thereafter, the gate valve G is opened and the substrate W in the LLM 12 is unloaded to the VTM 11 by the transfer robot 110.

Further, while keeping the pressure in the LLM 12 at approximately the same pressure as the pressure in the VTM 11, the transfer robot 110 loads the substrate W from the VTM 11 into the LLM 12 via the gate valve G, and the gate valve G is closed. Thereafter, the pressure in the LLM 12 is increased to approximately the same pressure as a pressure in the EFEM 13. Thereafter, the gate valve G is opened, and the substrate W in the LLM 12 is unloaded to the EFEM 13.

A plurality of load ports 14 are provided on a sidewall of the EFEM 13 opposite a sidewall on which the gate valve G is provided. Each of the load ports 14 is connected to a container such as a FOUP (Front Opening Unified Pod) that can accommodate a plurality of substrates W. An aligner module or the like that changes an orientation of the substrate W may be provided in the EFEM 13.

The pressure inside the EFEM 13 is kept at, for example, atmospheric pressure. A transfer robot 130 is provided in the EFEM 13. The transfer robot 130 transfers the substrate W between the LLM 12 and the container connected to the load port 14. An FFU (Fan Filter Unit) or the like is provided above the EFEM 13, and dry air from which particles and the like have been removed is supplied into the EFEM 13 from above to form a downflow in the EFEM 13. In this embodiment, the pressure inside the EFEM 13 is kept at atmospheric pressure, but in another embodiment, the pressure inside the EFEM 13 may be controlled to become a positive pressure. Thus, it is possible to prevent particles and the like from entering the EFEM 13 from outside.

A control device 15 includes a memory, a processor, and an input/output interface. The memory stores a control program, processing recipes, and other data. The processor reads and executes the control program from the memory, and controls individual components of the manufacturing system 10 via the input/output interface based on the recipes stored in the memory.

### Configuration Example of Film Forming Apparatus 20 and Film Forming Apparatus 50

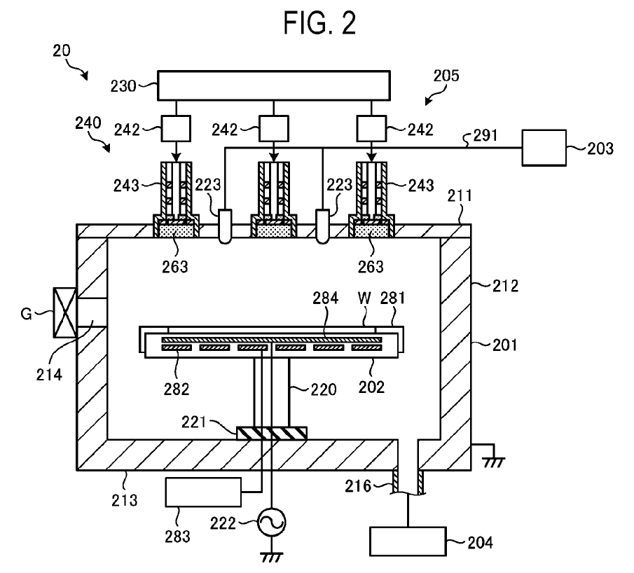

FIG. 2 illustrates an example of the film forming apparatus 20. The film forming apparatus 50 has the same configuration as that of the film forming apparatus 20 shown in FIG. 2. The film forming apparatus 20 shown in FIG. 2 includes a chamber 201, a stage 202, a gas supplier 203, an exhauster 204, and a microwave introducer 205. The chamber 201 accommodates the substrate W. The stage 202 supports the substrate W. The gas supplier 203 supplies a gas into the chamber 201. The exhauster 204 exhausts a gas from the chamber 201. The microwave introducer 205 generates microwaves for generating plasma in the chamber 201 and introduces the microwaves into the chamber 201.

The chamber 201 is made of a metallic material such as aluminum or an alloy thereof, has a substantially cylindrical shape, and includes a plate-shaped ceiling wall 211, a bottom wall 213, and a sidewall 212 connecting the ceiling wall 211 and the bottom wall 213. The microwave introducer 205 is provided at a top of the chamber 201 and functions as a plasma generator that introduces electromagnetic waves (microwaves) into the chamber 201 to generate plasma. The microwave introducer 205 will be described in detail later.

The ceiling wall 211 has a plurality of openings into which microwave radiation mechanisms and gas introducers (described later) of the microwave introducer 205 are inserted. The sidewall 212 has a load/unload port 214 for loading and unloading the substrate W between the chamber 201 and a transfer chamber (not shown) adjacent to the chamber 201. The load/unload port 214 is opened and closed by a gate valve G. The exhauster 204 is provided on the bottom wall 213. The exhauster 204 is provided in an exhaust pipe 216 connected to the bottom wall 213 and includes a vacuum pump and a pressure control valve. The chamber 201 is evacuated via the exhaust pipe 216 by the vacuum pump of the exhauster 204. A pressure inside the chamber 201 is controlled by the pressure control valve.

The stage 202 is generally disk-shaped and made of ceramic such as aluminum nitride. The stage 202 is supported by a cylindrical support 220 and a base 221, both of which are made of ceramic such as aluminum nitride and extend upward from a center of a bottom of the chamber 201. A guide ring 281 for guiding the substrate W is provided on an outer edge of the stage 202. Further, inside the stage 202, lift pins (not shown) for raising and lowering the substrate W are provided so as to protrude and retract with respect to an upper surface of the stage 202.

Further, a resistance-heating type heater 282 is embedded in the stage 202. The heater 282 receives electric power from a heater power supply 283 to heat the substrate W above the heater 282 via the stage 202. A thermocouple (not shown) is also inserted into the stage 202, and a heating temperature of the substrate W can be controlled to a predetermined temperature, for example, within a range of 200 degrees C to 1,000 degrees C based on a signal from the thermocouple. Furthermore, an electrode 284 having a size approximately the same as that of the substrate W is embedded above the heater 282 in the stage 202, and a radio frequency bias power supply 222 is electrically connected to the electrode 284. A radio frequency bias power for drawing ions into the stage 202 is applied from the radio frequency bias power supply 222. The radio frequency bias power supply 222 may not be provided according to characteristics of plasma processing.

A plurality of gas introduction nozzles 223 are inserted into the openings formed in the ceiling wall 211 of the chamber 201. A gas supplier 203 is connected to the respective gas introduction nozzles 223 via a gas supply pipe 291. The gas supplier 203 is a processing gas supply source. For example, when forming a graphene film, a mixed gas containing a rare gas and a carbon-containing gas is used as the processing gas. For example, argon is used as the rare gas. For example, a hydrocarbon gas expressed as CₓH_{y} (where x and y are natural numbers), such as ethylene (C₂H₄), is used as the carbon-containing gas. In addition, for example, when forming a silicon-containing film as a sealing film, a mixed gas containing a silicon-containing gas, a reaction gas, and a rare gas is used as the processing gas. For example, silane (SiH₄), dichlorosilane (DCS), or the like is used as the silicon-containing gas. Further, nitrogen, ammonia, oxygen, or the like is used as the reaction gas. Further, argon, helium, or the like is used as the rare gas. The gas supplier 203 is provided with a valve and a flow rate controller for each gas type, and a flow rate of each gas type is adjusted individually. Further, a hydrogen-containing gas, such as hydrogen gas, may be added to the processing gas.

As described above, the microwave introducer 205 is provided over the chamber 201 and functions as a plasma generator for introducing electromagnetic waves (microwaves) into the chamber 201 to generate plasma.

The microwave introducer 205 has the ceiling wall 211 of the chamber 201, a microwave output 230, and an antenna unit 240. The ceiling wall 211 functions as a top plate. The microwave output 230 generates microwaves, and distributes and outputs the microwaves into multiple paths. The antenna unit 240 radiates the microwaves, which has been output from the microwave output 230, into the chamber 201.

The microwave output 230 includes a microwave power supply, a microwave oscillator, an amplifier, and a distributor. The microwave oscillator is in a solid state and generates microwaves at, for example, 860 MHz (e.g., PLL oscillation). A frequency of the microwaves is not limited to 860 MHz, and may range from 700 MHz to 10 GHz, such as 2.45 GHz, 8.35 GHz, 5.8 GHz, and 1.98 GHz. The amplifier amplifies the microwaves generated by the microwave oscillator. The distributor distributes the microwaves amplified by the amplifier into multiple paths. The distributor distributes the microwaves while matching input-side and output-side impedances.

The antenna unit 240 includes a plurality of antenna modules. Each of the plurality of antenna modules introduces the microwaves distributed by the distributor of the microwave output 230 into the chamber 201. The plurality of antenna modules have the same configuration. Each of the antenna modules includes an amplifier 242 that mainly amplifies and outputs the distributed microwaves, and a microwave radiation mechanism 243 that radiates the microwaves output from the amplifier 242 into the chamber 201.

The amplifier 242 includes a phase shifter, a variable gain amplifier, a main amplifier, and an isolator. The phase shifter changes a phase of the microwaves. The variable gain amplifier adjusts a power level of the microwaves input to the main amplifier. The main amplifier is configured as a solid-state amplifier. The isolator separates reflected microwaves that are reflected by the antenna unit of the microwave radiation mechanism 243 (described later) toward the main amplifier.

For example, as shown in FIG. 2, the plurality of microwave radiation mechanisms 243 are provided in the ceiling wall 211. Each of the microwave radiation mechanisms 243 includes a cylindrical outer conductor and an inner conductor provided coaxially in the outer conductor. The microwave radiation mechanism 243 includes a coaxial tube having a microwave transmission path between the outer conductor and the inner conductor, and an antenna that radiates microwaves into the chamber 201. A microwave transmission plate 263 inserted into the ceiling wall 211 is provided on a lower surface of the antenna, and a lower surface of the microwave transmission plate 263 is exposed to an internal space of the chamber 201. The microwaves that pass through the microwave transmission plate 263 generate plasma in the internal space of the chamber 201. In other words, the microwave radiation mechanism 243 is an example of a plasma source.

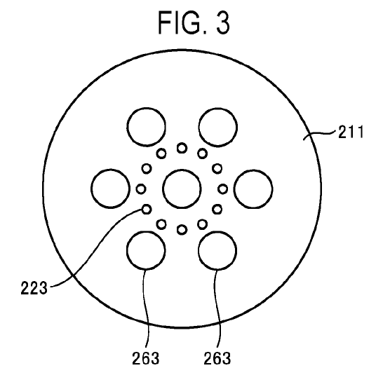

FIG. 3 is a schematic diagram illustrating an example of the ceiling wall 211. In this embodiment, as shown in FIG. 3, seven microwave radiation mechanisms 243 are provided on the ceiling wall 211, and the corresponding microwave transmission plates 263 are evenly disposed in the ceiling wall 211 in a hexagonal close-packed arrangement. That is, one of the seven microwave transmission plates 263 is disposed approximately at a center of the ceiling wall 211, and the other six microwave transmission plates 263 are disposed around the one microwave transmission plate 263. These seven microwave transmission plates 263 are disposed so that adjacent microwave transmission plates 263 are equi-spaced. The center of the ceiling wall 211 is an example of a central region, and a region around the microwave radiation mechanism 243 disposed at the center of the ceiling wall 211 is an example of a peripheral region. That is, one microwave radiation mechanism 243 is disposed in the central region, and six microwave radiation mechanisms 243 are disposed in the peripheral region. Further, the plurality of gas introduction nozzles 223 are disposed to surround the microwave transmission plate 263 disposed at the center. In the following, the microwave radiation mechanism 243 disposed in the central region will be referred to as a central microwave radiation mechanism 243, and the microwave radiation mechanisms 243 disposed in the peripheral regions will be referred to as peripheral microwave radiation mechanisms 243. In addition, the number of microwave radiation mechanisms 243 is not limited to seven, and may be less than seven or more than seven.

### Configuration Example of Film Forming Apparatus 30

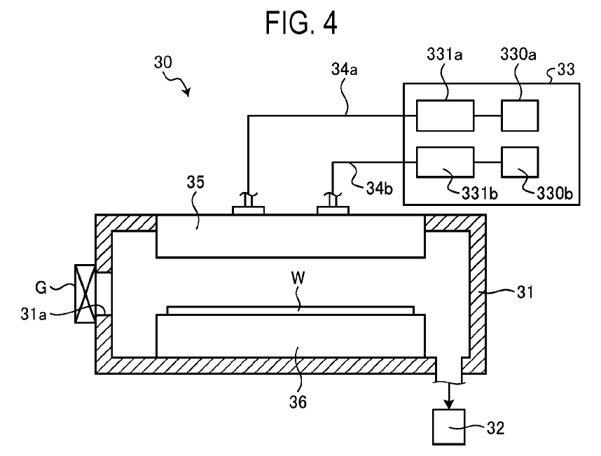

FIG. 4 illustrates an example of the film forming apparatus 30. The film forming apparatus 30 includes a chamber 31, an exhauster 32, a gas supplier 33, a shower head 35, and a stage 36. In this embodiment, the film forming apparatus 30 is, for example, a chemical vapor deposition (CVD) apparatus.

The exhauster 32 includes a vacuum pump that exhausts a gas from the chamber 31 and a pressure regulation valve that regulates a pressure inside the chamber 31. An inside of the chamber 31 is controlled to a vacuum atmosphere having a predetermined pressure by the exhauster 32.

The gas supplier 33 that supplies multiple types of raw material monomers is connected to the chamber 31 via the shower head 35. In this embodiment, the multiple types of raw material monomers are, for example, an isocyanate and an amine. The isocyanate is an example of a first monomer, and the amine is an example of a second monomer. The gas supplier 33 includes a raw material source 330a, a raw material source 330b, a vaporizer 331a, and a vaporizer 331b. The raw material source 330a accommodates, for example, an isocyanate liquid. The raw material source 330b accommodates, for example, an amine liquid.

The vaporizer 331a vaporizes the isocyanate liquid supplied from the raw material source 330a. The isocyanate vapor vaporized by the vaporizer 331a is introduced into the shower head 35 via a pipe 34a. The vaporizer 331b vaporizes the amine liquid supplied from the raw material source 330b. The amine vapor vaporized by the raw material supply source 330b is introduced into the shower head 35 via a pipe 34b.

The shower head 35 is provided, for example, in an upper portion of the chamber 31, and has a number of discharge ports formed on a lower surface of the shower head 35. The shower head 35 discharges the isocyanate vapor introduced via the pipe 34a and the amine vapor introduced via the pipe 34b into the chamber 31 in a shower-like manner from individual discharge ports.

The stage 36 is provided in the chamber 31. The stage 36 includes a temperature controller (not shown). The substrate W is loaded into the chamber 31 via an opening 31a formed in a sidewall of the chamber 31, and is placed on the stage 36. The opening 31a is opened and closed by a gate valve G. The stage 36 includes the temperature controller, which controls a temperature of the substrate W to a temperature appropriate for vapor deposition polymerization of the raw material monomers supplied from the gas supplier 33. The temperature appropriate for vapor deposition polymerization may be set according to a type of raw material monomer. The temperature appropriate for vapor deposition polymerization is, for example, within a range of 60 degrees C to 100 degrees C.

By causing a vapor deposition polymerization reaction of two types of raw material monomers to occur on a surface of the substrate W in the film forming apparatus 30 described above, a polymer organic film is formed on the surface of the substrate W. When the two types of raw material monomers are an isocyanate and an amine, a polymer organic film having polyurea bonds is formed on the surface of the substrate W.

### Configuration Example of Plasma Processing Apparatus 40

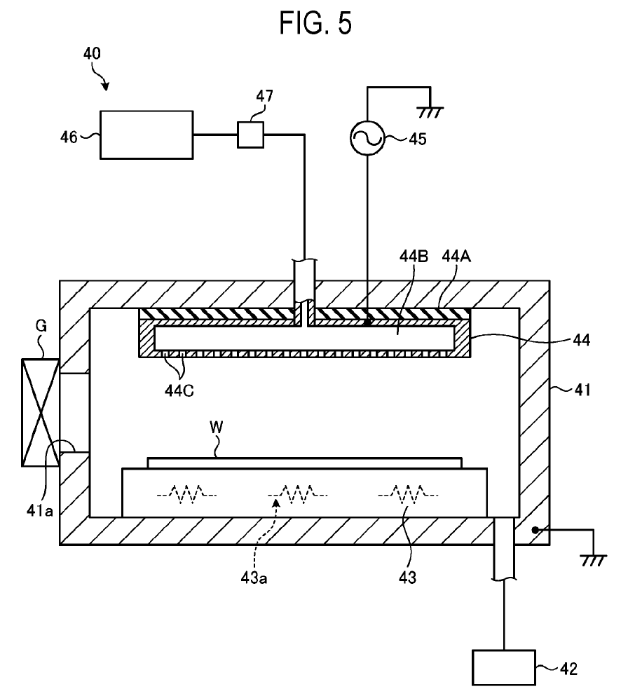

FIG. 5 illustrates an example of the plasma processing apparatus 40. The plasma processing apparatus 40 includes a chamber 41 made of a conductive material. The chamber 41 is grounded. An exhauster 42 which exhausts a gas from the chamber 41 and controls a pressure inside the chamber 41 to a predetermined level is connected to the chamber 41.

A stage 43 for placing the substrate W thereon is provided in the chamber 41. The substrate W, which is loaded into the chamber 41 via an opening 41a formed in a sidewall of the chamber 41, is placed on the stage 43. The opening 41a is opened and closed by a gate valve G. A heater 43a for heating the substrate W is provided in the stage 43. The stage 43 is electrically connected to a bottom of the chamber 41 and functions as an anode electrode. A shower head 44 is provided above the stage 43 so as to face an upper surface of the stage 43. The shower head 44 is supported by an upper portion of the chamber 41 via an insulator 44A. A power supply 45 that supplies radio frequency power for generating plasma is connected to the shower head 44. The shower head 44 functions as a cathode electrode relative to the stage 43.

A gas source 46 supplies a processing gas. A flow rate controller 47 adjusts a flow rate of the processing gas supplied from the gas source 46 and supplies the processing gas into a diffusion space 44B of the shower head 44. The processing gas supplied into the diffusion space 44B is diffused in the diffusion space 44B and is supplied in a shower-like manner into the chamber 41 from a plurality of discharge ports 44C formed in a lower surface of the diffusion space 44B. While one gas source 46 and one flow rate controller 47 are shown in FIG. 5, actually, a set of the gas source 46 and the flow rate controller 47 is provided for each type of gas used.

The processing gas supplied into the chamber 41 via the shower head 44 is converted into plasma by radio frequency power supplied into the chamber 41 by the power supply 45. Thereafter, the substrate W is subjected to processing such as etching by ions and active species contained in the plasma.

### Configuration Example of Heating Apparatus 60

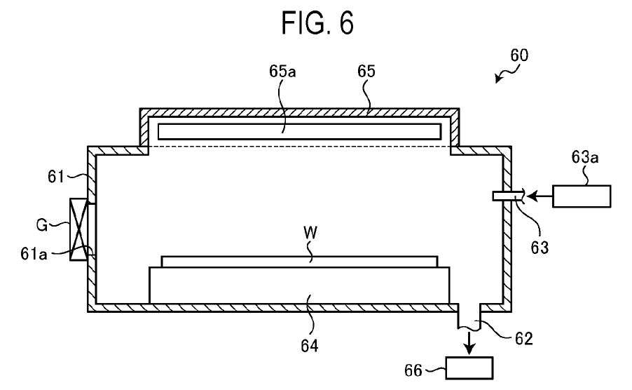

FIG. 6 illustrates an example of the heating apparatus 60. The heating apparatus 60 includes a chamber 61, an exhaust pipe 62, a supply pipe 63, a stage 64, and a lamp house 65.

The stage 64 for placing the substrate W thereon is provided in the chamber 61. The lamp house 65 is provided at a position facing a surface of the stage 64 on which the substrate W is placed. A lamp 65a such as an infrared lamp is disposed in the lamp house 65.

A gas supplier 63a is connected to a sidewall of the chamber 61 via the supply pipe 63. The gas supplier 63a supplies an inert gas such as N₂ gas into the chamber 61 via the supply pipe 63. An opening 61a for loading and unloading the substrate W is also formed in the sidewall of the chamber 61. The opening 61a is opened and closed by a gate valve G.

An exhauster 66 is connected to a bottom of the chamber 61 via the exhaust pipe 62. The exhauster 66 includes a pressure regulation valve. The exhauster 66 exhausts a gas from the chamber 61 and controls the pressure regulation valve so that a pressure inside the chamber 61 becomes a predetermined pressure.

In a state in which the substrate W is placed on the stage 64 and the inert gas is supplied into the chamber 61 via the supply pipe 63, the lamp 65a is turned on to heat the substrate W to a predetermined temperature in an inert gas atmosphere.

### Semiconductor Device Manufacturing Method

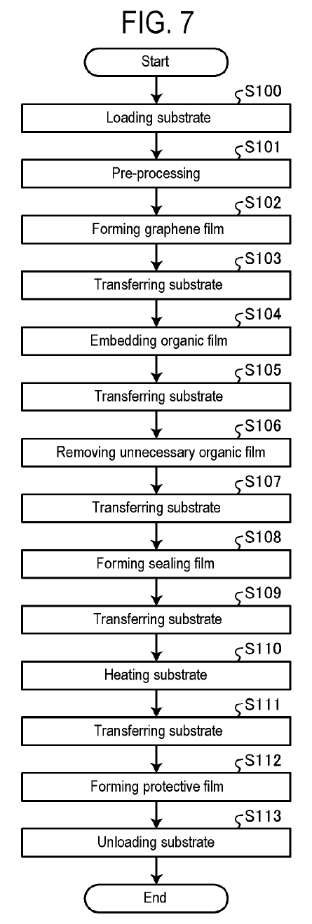

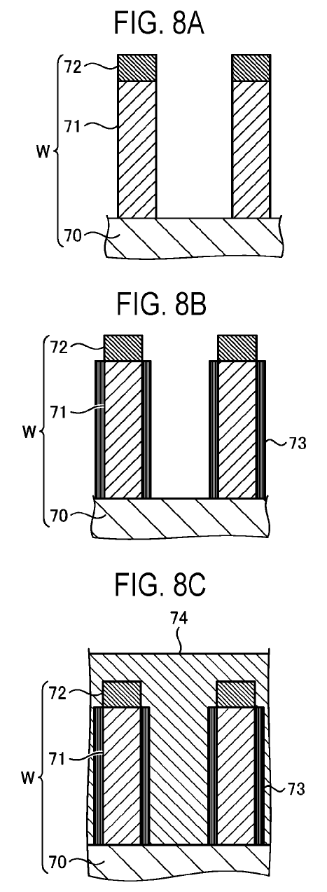

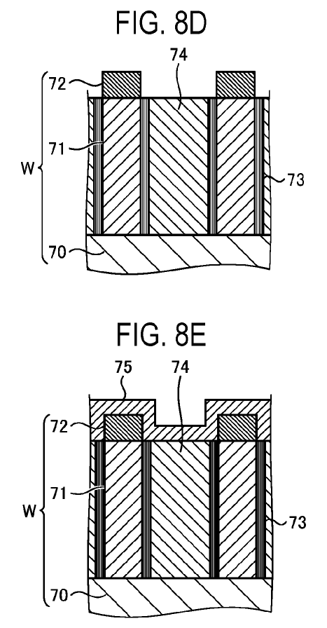

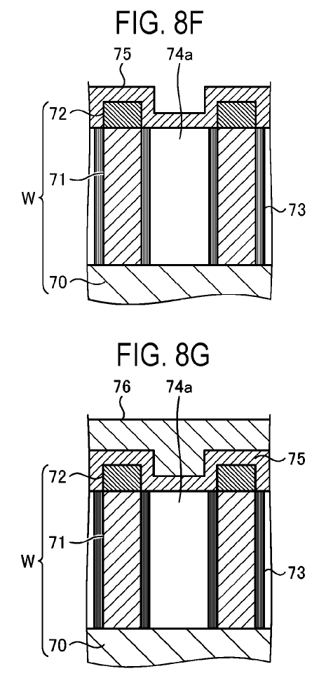

FIG. 7 is a flowchart illustrating an example of a semiconductor device manufacturing method according to a first embodiment. The manufacturing method shown in FIG. 7 is implemented by the control device 15 controlling individual components of the manufacturing system 10. The following description will be given with reference to FIGS. 8A to 8G.

First, the substrate W is loaded into the chamber 201 of the film forming apparatus 20 (step S100). Step S100 is an example of step a). In step S100, the substrate W having a structure shown in FIG. 8A is loaded into the film forming apparatus 20 by the transfer robot 110 in the VTM 11. The substrate W has a pattern including a plurality of metal-containing layers 71 formed on an underlayer 70 and a dielectric layer 72 formed on each of the metal-containing layers 71. A semiconductor device is fabricated from the substrate W. In this embodiment, at least a surface of the underlayer 70 is formed of, for example, TiN or TaN. The metal-containing layer 71 contains at least one of, for example, Ru, Co, Cu, Mo, Ni, or W. The metal-containing layer 71 is used, for example, as wiring in the semiconductor device. The dielectric layer 72 is, for example, a silicon-containing film such as a silicon nitride film.

Subsequently, pre-processing is performed for the substrate W (step S101). Step S101 is an example of step b). In step S101, a modifying gas is supplied into the chamber 201 to modify a sidewall of each metal-containing layer 71. In step S101, pre-processing is performed by the film forming apparatus 20 under, for example, the following processing conditions.

Pressure in the chamber 201: 50 mTorr to 1 Torr (6.7 to 133 Pa)
Flow rate ratio of gases contained in the modifying gas: H₂:Ar = 200:2 to 50:50
Temperature of the substrate W: 250 to 550 degrees C
Processing time: 5 seconds to 15 minutes

The pre-processing of step S101 reduces an oxide film unintentionally formed on a surface of the sidewall of the metal-containing layer 71 during the transfer of the substrate W. The modifying gas used in the pre-processing of step S101 includes an inert gas and a hydrogen-containing gas. In this embodiment, the inert gas includes at least one of a rare gas such as He gas or Ar gas, or N₂ gas, and the hydrogen-containing gas includes at least one of H₂ gas or NH₃ gas.

The pre-processing of step S101 may use plasma. Plasma pre-processing is performed under, for example, the following conditions.

Pressure in the chamber 201: 50 mTorr to 1 Torr (6.7 to 133 Pa)
Flow rate of the hydrogen-containing gas (e.g., H₂ gas): 250 to 1,000 sccm (0.42 to 1.69 Pa·m³/s)
Microwave power: 100 to 1,500 W
Temperature of the substrate W: 250 to 550 degrees C
Processing time: 5 seconds to 15 minutes

Subsequently, a graphene film is formed on the sidewall of the metal-containing layer 71 (step S102). Step S102 is an example of step c). In step S102, plasma is generated from a first processing gas including a carbon-containing gas in the chamber 201, and the generated plasma is used to form a graphene film 73 on the sidewall of the metal-containing layer 71. In step S102, the graphene film 73 is formed by the film forming apparatus 20 under, for example, the following processing conditions.

Pressure in the chamber 201: 1 mTorr to 100 mTorr (0.133 Pa to 13.3 Pa)

First processing gas: C₂H₂/Ar = 5 to 100 sccm/50 to 1,000 sccm (0.00845 to 0.17 Pa·m³/s/0.0845 to 1.7 Pa·m³/s)

Microwave power: 300 to 3,000 W

Temperature of substrate W: 250 to 550 degrees C

Processing time: 5 seconds to 15 minutes

By the processing of step S102, the graphene film 73 is formed on the sidewall of the metal-containing layer 71, as shown in FIG. 8B. In step S102, the pressure in the chamber 201 may be 50 mTorr to 100 mTorr (6.67 Pa to 13.3 Pa). The microwave power may be 300 W to 1,500 W. The first processing gas includes a carbon-containing gas and an inert gas. The first processing gas may include a hydrogen-containing gas such as H₂ gas or NH₃ gas. In this embodiment, the carbon-containing gas is a hydrocarbon gas (e.g., C₂H₂ gas or C₂H₄ gas) represented by CₓH_{y} (where x and y are natural numbers), and the inert gas is a rare gas such as He gas or Ar gas.

Subsequently, the substrate W is transferred from the film forming apparatus 20 to the film forming apparatus 30 (step S103). In step S103, the substrate W is unloaded from the chamber 201 of the film forming apparatus 20 and loaded into the chamber 31 of the film forming apparatus 30 by the transfer robot 110 in the VTM 11.

Subsequently, a thermally decomposable organic film is embedded in a groove formed by adjacent metal-containing layers 71 in the substrate W (step S104). Step S104 is an example of step d). In step S104, a first monomer and a second monomer are supplied into the chamber 31. A vapor deposition polymerization reaction of the first monomer and the second monomer is caused to occur on the surface of the substrate W, thereby forming a thermally decomposable polymer organic film on the surface of the substrate W. In this embodiment, the first monomer is, for example, an isocyanate, the second monomer is, for example, an amine, and the polymer organic film has polyurea bonds. As a result, for example, as shown in FIG. 8C, an organic film 74 is embedded in the groove formed by the adjacent metal-containing layers 71.

In step S104, the organic film 74 is formed on the surface of the substrate W under, for example, the following processing conditions.

Pressure in the chamber 31: 0.5 to 20 Torr (66.7 to 2,666 Pa)
Flow rate of the isocyanate vapor: 1 to 20 sccm (0.0017 to 0.034 Pa·m³/s)
Flow rate of the amine vapor: 1 to 20 sccm (0.0017 to 0.034 Pa·m³/s)
Temperature of the substrate W: 40 to 150 degrees C

Subsequently, the substrate W is transferred from the film forming apparatus 30 to the plasma processing apparatus 40 (step S105). In step S105, the substrate W is unloaded from the chamber 31 of the film forming apparatus 30 and loaded into the chamber 41 of the plasma processing apparatus 40 by the transfer robot 110 in the VTM 11.

Subsequently, an unnecessary organic film 74 on the substrate W is removed (step S106). Step S106 is an example of step h). In step S106, plasma is generated from the processing gas in the chamber 41. As shown in FIG. 8D, for example, the unnecessary organic film 74 formed on the dielectric layer 72 is removed by the generated plasma. In other words, the unnecessary organic film 74 is removed so as to expose the dielectric layer 72. In step S106, the unnecessary organic film 74 is removed by the plasma processing apparatus 40 under, for example, the following processing conditions.

Pressure in the chamber 41: 0.05 to 1.0 Torr (6.67 to 133 Pa)
Processing gas: H₂/N₂ = 100 to 300 sccm/100 to 300 sccm (0.17 to 0.51 Pa·m³/s/0.17 to 0.51 Pa·m³/s)
Radio frequency power: 100 to 400 W
Temperature of the substrate W: 40 to 80 degrees C

Subsequently, the substrate W is transferred from the plasma processing apparatus 40 to the film forming apparatus 50 (step S107). In step S107, the substrate W is unloaded from the chamber 41 of the plasma processing apparatus 40 and loaded into the chamber 201 of the film forming apparatus 50 by the transfer robot 110 in the VTM 11.

Subsequently, a sealing film is formed on the organic film 74 (step S108). Step S108 is an example of step e). In step S108, plasma is generated in the chamber 201 from, for example, a processing gas containing an organic aminosilane. For example, as shown in FIG. 8E, a sealing film 75 is formed on the organic film 74 by the generated plasma. In this embodiment, the sealing film 75 is, for example, a silicon oxide film. The sealing film 75 may also be another silicon-containing film, such as a silicon nitride film. In step S108, the sealing film 75 is formed by the film forming apparatus 50 under, for example, the following processing conditions.

Pressure in the chamber 201: 0.1 to 10 Torr (13.3 to 1,333 Pa)
Processing gas: organic aminosilane = 10 to 50 sccm (0.017 to 0.085 Pa·m³/s)
Microwave power: 50 to 200 W
Temperature of the substrate W: 20 to 100 degrees C

Subsequently, the substrate W is transferred from the film forming apparatus 50 to the heating apparatus 60 (step S109). In step S109, the substrate W is unloaded from the chamber 201 of the film forming apparatus 50 to the chamber 61 of the heating apparatus 60 by the transfer robot 110 in the VTM 11.

Subsequently, the substrate W is heated (step S110). Step S110 is an example of step f). In step S110, the substrate W is heated to cause the organic film 74 to be thermally decomposed and detached via the sealing film 75. As a result, for example, as shown in FIG. 8F, an air gap 74a is formed between the groove formed by adjacent metal-containing layers 71 and the sealing film 75. In step S110, the substrate W is heated under, for example, the following processing conditions.

Pressure in the chamber 61: 0.5 to 20 Torr (66.7 to 2,666 Pa)
Gas supplied into the chamber 61: N₂ = 200 to 2,000 sccm (0.34 to 3.4 Pa·m³/s)
Temperature of the substrate W: 350 to 450 degrees C

Subsequently, the substrate W is transferred from the heating apparatus 60 to the film forming apparatus 50 (step S111). In step S111, the substrate W is unloaded from the chamber 61 of the heating apparatus 60 and loaded back into the chamber 201 of the film forming apparatus 50 by the transfer robot 110 in the VTM 11.

Subsequently, a protective film is formed on the sealing film 75 (step S112). In step S112, plasma is generated in the chamber 201 from, for example, a processing gas containing an organic aminosilane. For example, as shown in FIG. 8G, a protective film 76 is formed on the sealing film 75 by the generated plasma. In this embodiment, the protective film 76 is, for example, a silicon nitride film. In step S112, the protective film 76 is formed by the film forming apparatus 50 under, for example, the following processing conditions.

Pressure in the chamber 201: 0.1 to 10 Torr (13.3 to 1,333 Pa)
Processing gas: organic aminosilane = 10 to 50 sccm (0.017 to 0.085 Pa·m³/s)
Microwave power: 50 to 200 W
Temperature of the substrate W: 20 to 100 degrees C

Subsequently, the substrate W is unloaded from the film forming apparatus 50 (step S113), and the semiconductor device manufacturing method shown in this flowchart ends.

### Thickness of Sealing Film 75

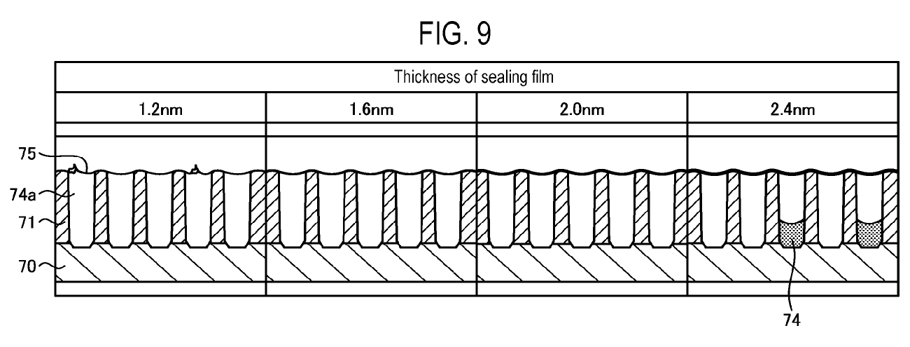

FIG. 9 illustrates an example of a state of the air gap 74a for each thickness of the sealing film 75. For example, as shown in FIG. 9, when a thickness of the sealing film 75 was 1.2 nm, the sealing film 75 was torn in places. Therefore, the thickness of the sealing film 75 may be larger than 1.2 nm.

For example, as shown in FIG. 9, when the thickness of the sealing film 75 was 2.4 nm, the organic film 74 in the groove formed by the adjacent metal-containing layers 71 was not completely detached and remains even after the substrate W is heated. Therefore, the thickness of the sealing film 75 may be smaller than 2.4 nm.

On the other hand, when the thickness of the sealing film 75 was 1.6 nm and 2.0 nm, for example, as shown in FIG. 9, the organic film 74 was not observed in the groove formed by the adjacent metal-containing layers 71. Further, the sealing film 75 was not torn. Therefore, the thickness of the sealing film 75 may be 1.2 nm or more and 2.0 nm or less.

### Resistance of Metal-Containing Layer 71

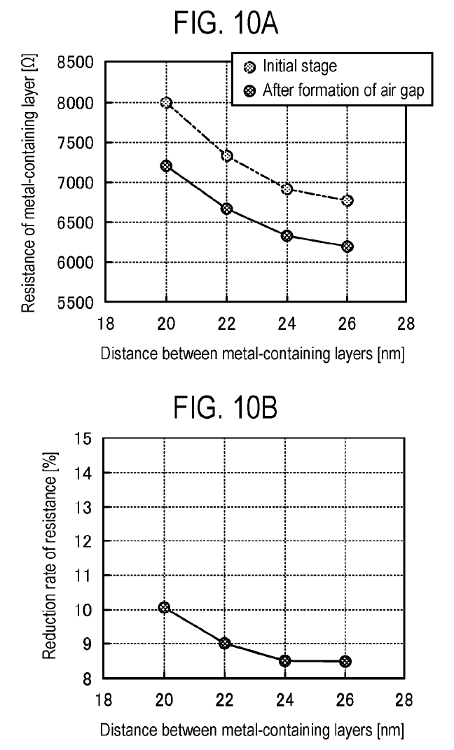

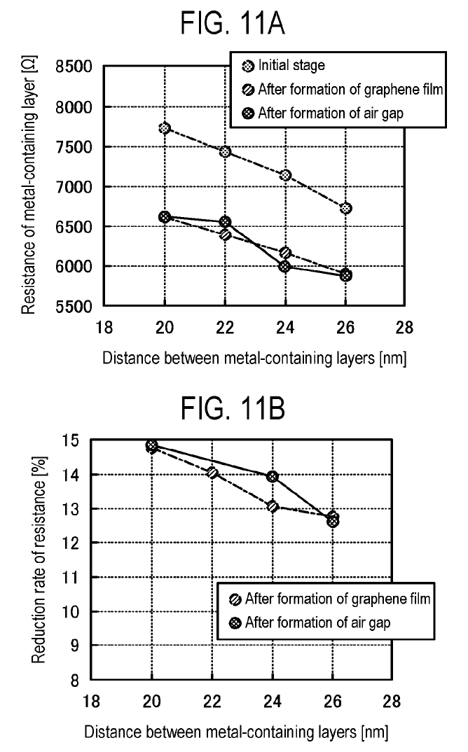

As a comparative example, a resistance of the metal-containing layer 71 was measured when the air gap 74a was formed on the sidewall of the metal-containing layer 71 without forming the graphene film 73. The results shown in FIGS. 10A and 10B were obtained. In this comparative example, by heating the metal-containing layer 71 to detach the organic film 74, crystal grains of the metal-containing layer 71 were enlarged and the resistance of the metal-containing layer 71 was reduced. Referring to FIG. 10B, in this comparative example, the resistance of the metal-containing layer 71 after the air gap 74a was formed was reduced by approximately 9% from an initial state.

On the other hand, in this embodiment in which the graphene film 73 was formed on the sidewall of the metal-containing layer 71 before forming the air gap 74a, the results as shown in FIGS. 11A and 11B were obtained. In this embodiment, the resistance of the metal-containing layer 71 was reduced by approximately 14% from an initial state in the stage of forming the graphene film 73 on the sidewall of the metal-containing layer 71. This reduction in resistance was maintained even after the air gap 74a was formed. Comparing FIGS. 10B and 11B, by forming the graphene film 73 on the sidewall of the metal-containing layer 71, a reduction rate in the resistance of the metal-containing layer 71 was increased by approximately 5% compared to a case where the graphene film 73 was not formed on the sidewall of the metal-containing layer 71. Therefore, in this embodiment, by forming the graphene film 73 on the sidewall of the metal-containing layer 71, the resistance of the metal-containing layer 71 for use in wiring in a semiconductor device can be further reduced.

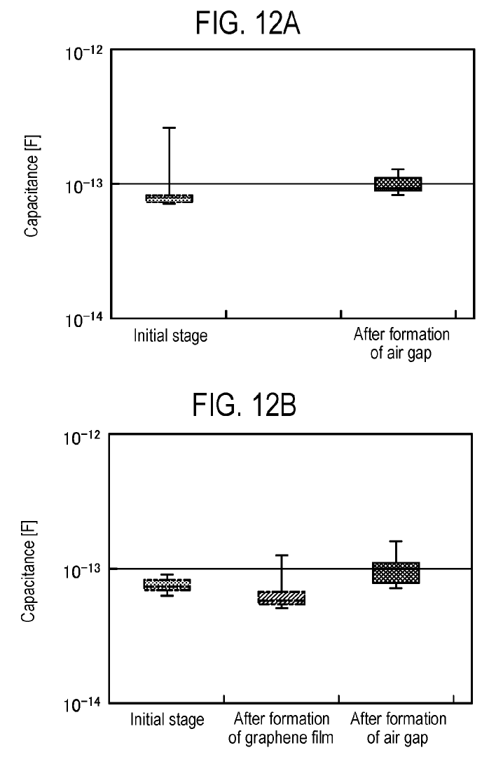

FIG. 12A is a diagram showing an example of a capacitance between the metal-containing layers 71 in the comparative example. FIG. 12B is a diagram showing an example of a capacitance between the metal-containing layers 71 in the first embodiment. Referring to FIGS. 12A and 12B, in both the comparative example and the first embodiment, the capacitance between the metal-containing layers 71 is hardly changed between the initial state and a state after the air gap 74a is formed. In the initial state, as shown in FIG. 8A, for example, there is an empty space between adjacent metal-containing layers 71. The fact that the capacitance between the metal-containing layers 71 is almost the same in the initial state and the state after the formation of the air gap 74a suggests that a sufficiently large air gap 74a is formed between the adjacent metal-containing layers 71. By forming the sufficiently large air gap 74a between the adjacent metal-containing layers 71, the capacitance between the adjacent metal-containing layers 71 can be reduced.

As described above, in this embodiment, the resistance of the metal-containing layer 71 can be reduced, and the capacitance between the metal-containing layers 71 can be reduced by forming the air gap 74a between adjacent metal-containing layers 71. Thus, it is possible to reduce delay of signals flowing through the metal-containing layer 71 used as wiring in the semiconductor device.

The first embodiment has been described above. As described above, the semiconductor device manufacturing method according to the first embodiment includes steps a), b), c), d), e), and f). In step a), a substrate (substrate W) having a pattern including a plurality of metal-containing layers (metal-containing layers 71) formed on an underlayer (underlayer 70) and a dielectric layer (dielectric layers 72) formed on each of the metal-containing layers is prepared in a chamber (chamber 201). In step b), a modifying gas is supplied into the chamber to modify sidewalls of the metal-containing layers. In step c), plasma is generated from a first processing gas including a carbon-containing gas in the chamber, and a graphene film (graphene film 73) is formed on the sidewalls of the metal-containing layers by using the generated plasma. In step d), a thermally decomposable organic film (organic film 74) is embedded in a groove formed by adjacent metal-containing layers. In step e), a sealing film (sealing film 75) is formed on the organic film embedded in the groove. In step f), the substrate is heated to thermally decompose the organic film, and the organic film is detached via the sealing film, thereby forming an air gap (air gap 74a) between the groove and the sealing film. Accordingly, it is possible to manufacture a semiconductor device with reduced signal delay.

The semiconductor device manufacturing method according to the first embodiment described above may further include, between step d) and step e), a step of removing the organic film formed on the dielectric layer. Thus, it is possible to form an air gap of a desired shape between adjacent metal-containing layers 71.

In the first embodiment described above, a thickness of the sealing film may be 1.6 nm or more and 2.0 nm or less. Thus, it is possible to form an air gap of a desired shape between adjacent metal-containing layers 71.

In the first embodiment described above, the sealing film may be a silicon oxide film or a silicon nitride film. Thus, it is possible to detach the organic film embedded between adjacent metal-containing layers 71.

In the first embodiment described above, the modifying gas may include an inert gas and a hydrogen-containing gas, and a flow rate ratio of the inert gas to the hydrogen-containing gas may be within a range of 200:2 to 50:50. Thus, it is possible to modify the sidewalls of the metal-containing layers 71 so that the graphene film adheres easily to the sidewalls of the metal-containing layers 71.

In the first embodiment described above, the inert gas contained in the modifying gas may include at least one of He gas, Ar gas, or N₂ gas. In addition, the hydrogen-containing gas contained in the modifying gas may include at least one of H₂ gas or NH₃ gas. Thus, it is possible to modify the sidewalls of the metal-containing layers 71 so that the graphene film adheres easily to the sidewalls of the metal-containing layers 71.

In the first embodiment described above, a temperature of the substrate in step c) may be 250 degrees C or higher and 550 degrees C or lower. Thus, it is possible to efficiently form the graphene film on the sidewalls of the metal-containing layers 71.

In the first embodiment described above, a temperature of the substrate in step d) may be 40 degrees C or higher and 150 degrees C or lower. Thus, it is possible to efficiently embed the organic film in the groove formed by adjacent metal-containing layers.

In the first embodiment described above, a temperature of the substrate in step e) may be 20 degrees C or higher and 100 degrees C or lower. Thus, it is possible to efficiently form the sealing film on the organic film.

In the first embodiment described above, a temperature of the substrate in step f) may be 350 degrees C or higher and 450 degrees C or lower. Thus, it is possible to efficiently detach the organic film via the sealing film.

In the first embodiment described above, a surface of the underlayer may be TiN or TaN. Thus, it is possible to suppress the graphene film from being formed on the underlayer.

In the first embodiment described above, the metal-containing layers may contain at least one of Ru, Co, or Cu. Thus, it is possible to efficiently form the graphene film on the metal-containing layers.

In the first embodiment described above, in step d), gases of a first monomer and a second monomer may be supplied into the chamber, and the organic film may be embedded in the groove by vapor deposition polymerization of the first monomer and the second monomer. Thus, it is possible to efficiently embed the organic film in the groove formed by the adjacent metal-containing layers.

In the first embodiment described above, the first monomer may be an isocyanate, the second monomer may be an amine, and the organic film contains urea bonds. Thus, it is possible to efficiently detach the organic film via the sealing film.

In addition, the first embodiment described above is directed to a semiconductor device manufacturing system (manufacturing system 10) including a first processing apparatus (film forming apparatus 20), a second processing apparatus (film forming apparatus 30), a third processing apparatus (film forming apparatus 50), a fourth processing apparatus (heating apparatus 60), and a control device (control device 15) that controls the first processing apparatus, the second processing apparatus, the third processing apparatus, and the fourth processing apparatus. The control device executes steps a), b), c), d), e), and f). In step a), a substrate (substrate W) having a pattern including a plurality of metal-containing layers (metal-containing layers 71) formed on an underlayer (underlayer 70) and a dielectric layer (dielectric layers 72) formed on each of the metal-containing layers is prepared in a chamber (chamber 201) of the first processing apparatus. In step b), a modifying gas is supplied into the chamber to modify sidewalls of the metal-containing layers. In step c), plasma is generated from a first processing gas including a carbon-containing gas in the chamber, and a graphene film (graphene film 73) is formed on the sidewalls of the metal-containing layers by using the generated plasma. In step d), a second processing apparatus is used to embed a thermally decomposable organic film (organic film 74) in a groove formed by adjacent metal-containing layers. In step e), a third processing apparatus is used to form a sealing film (sealing film 75) on the organic film embedded in the groove. In step f), a fourth processing apparatus is used to thermally decompose the organic film by heating the substrate, and the organic film is detached via the sealing film, thereby forming an air gap (air gap 74a) between the groove and the sealing film. Thus, it is possible to manufacture a semiconductor device with reduced signal delay.

### Second Embodiment

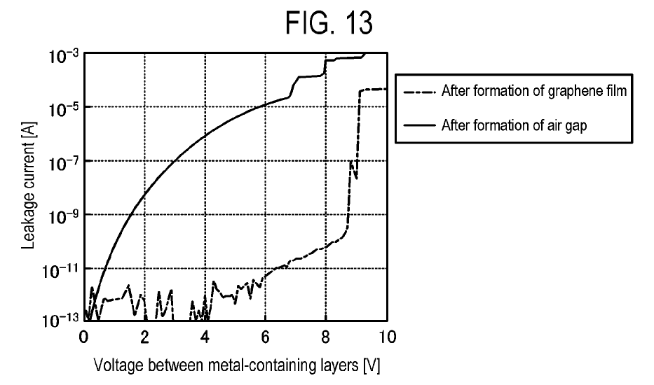

When the substrate W is heated in step S110 of the first embodiment, according to conditions, the organic film 74 in the groove formed by the adjacent metal-containing layers 71 may not be completely detached and may remain as residues. The residues in the groove may become conductive by heating. Therefore, for example, as shown in FIG. 13, a leakage current after the air gap 74a is formed may be greater than a leakage current at the stage when the graphene film 73 is formed. Therefore, in a second embodiment, in order to remove the residues after the air gap 74a is formed, a process of removing the organic film 74 is performed after heating the substrate W to form the air gap 74a.

### Semiconductor Device Manufacturing Method

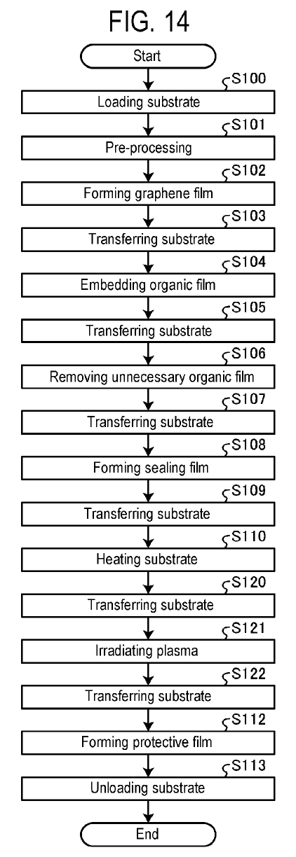

FIG. 14 is a flowchart showing an example of the semiconductor device manufacturing method according to the second embodiment. The manufacturing method shown in FIG. 14 is implemented by the control device 15 controlling individual components of the manufacturing system 10. The steps in FIG. 14 denoted by the same reference numerals as in FIG. 7 are the same as the steps described by using FIG. 7, except for the points described below. Thus, redundant descriptions thereof will be omitted.

After the substrate W is heated by the heating apparatus 60, the substrate W is unloaded from the heating apparatus 60 to the plasma processing apparatus 40 (step S120). In step S120, the transfer robot 110 in the VTM 11 unloads the substrate W from the chamber 61 of the heating apparatus 60 and loads the substrate W into the chamber 41 of the plasma processing apparatus 40.

Subsequently, the substrate W is irradiated with plasma (step S121). Step S121 is an example of step g). In step S121, plasma is generated from a processing gas in the chamber 41. In this embodiment, the processing gas is Ar gas. The processing gas used in step S121 is an example of a third processing gas that does not contain oxygen. The processing gas used in step S121 may be a rare gas other than Ar gas, or a gas that contains at least one of a rare gas, N₂ gas, or H₂ gas.

In step S121, plasma is generated under, for example, the following processing conditions.

Pressure in the chamber 41: 0.5 to 5 Torr (66.7 to 667 Pa)
Processing gas: Ar = 200 to 2,000 sccm (0.34 to 3.4 Pa·m³/s)
Radio frequency power: 50 to 500 W
Temperature of the substrate W: 300 to 400 degrees C

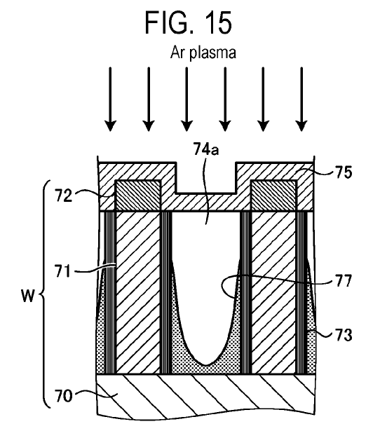

Thereafter, as shown in FIG. 15, for example, the generated plasma is irradiated onto the substrate W. As a result, active species and other substances contained in the plasma are supplied to a residue 77 remaining in the air gap 74a, and the residue 77 is decomposed. The decomposed residue 77 is detached via the sealing film 75.

Subsequently, the substrate W is transferred from the plasma processing apparatus 40 to the film forming apparatus 50 (step S122). In step S122, the substrate W is unloaded from the chamber 41 of the plasma processing apparatus 40 and loaded into the chamber 201 of the film forming apparatus 50 by the transfer robot 110 in the VTM 11. Thereafter, the processing from step S112 onward is executed.

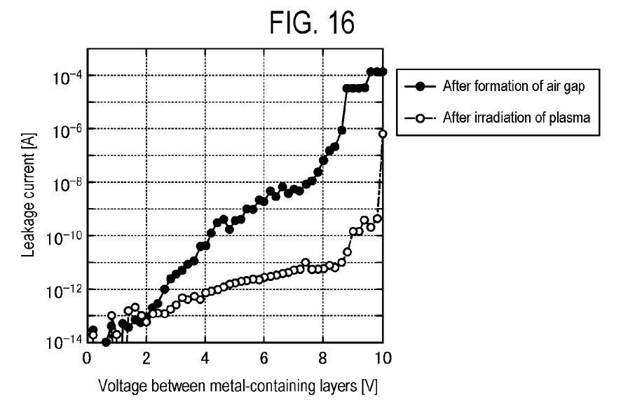

FIG. 16 shows an example of the leakage current in the second embodiment. When the plasma is irradiated after the air gap 74a is formed, the leakage current is reduced compared to before the plasma irradiation, as shown in FIG. 16, for example. Therefore, by irradiating with the plasma after the air gap 74a is formed, it is possible to reduce the leakage current between adjacent metal-containing layers 71.

The second embodiment has been described above. As described above, the semiconductor device manufacturing method according to the second embodiment further includes step g). In step g), the groove is irradiated with plasma via the sealing film after the air gap is formed in step f). Thus, it is possible to reduce the leakage current between adjacent metal-containing layers 71.

Further, in step g) of the second embodiment described above, plasma generated from a third processing gas that does not contain oxygen is irradiated into the groove via the sealing film. The third processing gas contains at least one of a rare gas, N₂ gas, or H₂ gas. Thus, it is possible to reduce the leakage current between adjacent metal-containing layers 71.

### Others

The technique disclosed herein is not limited to the embodiments described above, and various modifications may be made within the scope of the present disclosure.

For example, in the second embodiment described above, the substrate W is heated to form the air gap 74a, and then the plasma generated from the oxygen-free processing gas is irradiated onto the substrate W. However, the disclosed technique is not limited thereto. In another embodiment, the substrate W may be heated to form the air gap 74a, and then plasma generated from an oxygen-containing processing gas may be irradiated onto the substrate W. Thus, it is possible to efficiently detach the residue 77 remaining in the air gap 74a.

However, when using the plasma generated from the oxygen-containing processing gas to remove the residue 77, according to conditions, the graphene film 73 may also be removed by oxygen-derived active species in the plasma. Further, according to conditions, the oxygen-derived active species in the plasma may oxidize the sidewalls of the metal-containing layers 71, increasing the resistance of the metal-containing layers 71. Therefore, when using the plasma generated from the oxygen-containing processing gas to remove the residue 77, the following processing conditions may be used.

Pressure in the chamber 41: 0.5 to 1 Torr (66.7 to 133 Pa)
Processing gas: O₂ = 10 to 50 sccm (0.017 to 0.085 Pa∙m³/s)
Radio frequency power: 100 to 200 W
Temperature of the substrate W: 200 to 400 degrees C

Further, in each of the embodiments described above, the graphene film 73 is formed by using the film forming apparatus 20 having the plurality of microwave radiation mechanisms 243, but the disclosed technique is not limited thereto. In other embodiments, for example, the graphene film 73 may be formed by using a film forming apparatus having a single microwave radiation mechanism.

Further, in each of the embodiments described above, the film forming apparatus 20 that uses microwave plasma as a plasma source to form the graphene film 73 has been described by way of example, but the disclosed technique is not limited thereto. The plasma source is not limited to the microwave plasma, and any plasma source may be used as long as an apparatus forms the graphene film 73 on the substrate W by using plasma. For example, any plasma source such as capacitively coupled plasma, inductively coupled plasma, magnetron plasma, or the like may be used.

Further, in each of the embodiments described above, the organic film 74 of thermally decomposable polymer having urea bonds (-NH-CO-NH-) is formed on the surface of the substrate W by using an isocyanate as the first monomer and an amine as the second monomer, but the disclosed technique is not limited thereto. For example, an organic film of a thermally decomposable polymer having 2-aminoethanol bonds (-NH-CH₂-CH(OH)-) may be formed on the surface of the substrate W by using an epoxide as the first monomer and an amine as the second monomer. Alternatively, an organic film of a thermally decomposable polymer having urethane bonds (-NH-CO-O-) may be formed on the surface of the substrate W by using an isocyanate as the first monomer and an alcohol as the second monomer. Alternatively, an organic film of a thermally decomposable polymer having amide bonds (-NH-CO-) may be formed on the surface of the substrate W by using acyl halide as the first monomer and an amine as the second monomer. Alternatively, an organic film of a thermally decomposable polymer having imide bonds (-CO-N(-)-CO-) may be formed on the surface of the substrate W by using an carboxylic acid anhydride as the first monomer and an amine as the second monomer.

It should be noted that the embodiments disclosed herein are exemplary and not limitative in all respects. Indeed, the embodiments described above may be embodied in a variety of forms. Further, the embodiments described above may be omitted, replaced, or modified in various ways without departing from the scope and spirit of the attached claims.

In addition, the following supplementary notes are additionally disclosed regarding the above-described embodiments.

### Supplementary Note 1

A semiconductor device manufacturing method includes:
a) preparing, in a chamber, a substrate having a pattern including a plurality of metal-containing layers formed on an underlayer and a dielectric layer formed on each of the metal-containing layers;
b) modifying sidewalls of the metal-containing layers by supplying a modifying gas into the chamber;
c) generating plasma from a first processing gas including a carbon-containing gas in the chamber, and forming a graphene film on the sidewalls of the metal-containing layers by using the generated plasma;
d) embedding a thermally decomposable organic film in a groove formed by adjacent metal-containing layers;
e) forming a sealing film on the organic film embedded in the groove; and
f) forming an air gap between the groove and the sealing film, by heating the substrate to thermally decompose the organic film and detaching the organic film via the sealing film.

### Supplementary Note 2

The semiconductor device manufacturing method of Supplementary Note 1, further includes g) irradiating plasma into the groove via the sealing film after the air gap is formed in f).

### Supplementary Note 3

The semiconductor device manufacturing method of Supplementary Note 2, wherein in g), plasma generated from a second processing gas, which is an oxygen-containing gas, is irradiated into the groove via the sealing film.

### Supplementary Note 4

The semiconductor device manufacturing method of Supplementary Note 2, wherein in g), plasma generated from a third processing gas, which is an oxygen-free gas, is irradiated into the groove via the sealing film

### Supplementary Note 5

The semiconductor device manufacturing method of Supplementary Note 4, wherein the third processing gas includes at least one of a rare gas, N₂ gas, or H₂ gas.

### Supplementary Note 6

The semiconductor device manufacturing method of any one of Supplementary Note 1 to 5, further includes, between d) and e), h) removing the organic film formed on the dielectric layer.

### Supplementary Note 7

The semiconductor device manufacturing method of any one of Supplementary Note 1 to 6, wherein a thickness of the sealing film is 1.6 nm or more and 2.0 nm or less.

### Supplementary Note 8

The semiconductor device manufacturing method of any one of Supplementary Note 1 to 7, wherein the sealing film is a silicon oxide film or a silicon nitride film.

### Supplementary Note 9

The semiconductor device manufacturing method of any one of Supplementary Note 1 to 8, wherein the modifying gas includes an inert gas and a hydrogen-containing gas.

### Supplementary Note 10

The semiconductor device manufacturing method of Supplementary Note 9, wherein a flow rate ratio of the inert gas to the hydrogen-containing gas is within a range of 200:2 to 50:50.

### Supplementary Note 11

The semiconductor device manufacturing method of Supplementary Note 9 or 10, wherein the inert gas includes at least one of He gas, Ar gas, or N₂ gas.

### Supplementary Note 12

The semiconductor device manufacturing method of any one of Supplementary Note 9 to 11, wherein the hydrogen-containing gas includes at least one of H₂ gas or NH₃ gas.

### Supplementary Note 13

The semiconductor device manufacturing method of any one of Supplementary Note 1 to 12, wherein a temperature of the substrate in c) is 250 degrees C or higher and 550 degrees C or lower.

### Supplementary Note 14

The semiconductor device manufacturing method of any one of Supplementary Note 1 to 13, wherein a temperature of the substrate in d) is 40 degrees C or higher and 150 degrees C or lower.

### Supplementary Note 15

The semiconductor device manufacturing method of any one of Supplementary Note 1 to 14, wherein a temperature of the substrate in e) is 20 degrees C or higher and 100 degrees C or lower.

### Supplementary Note 16

The semiconductor device manufacturing method of any one of Supplementary Note 1 to 15, wherein a temperature of the substrate in f) is 350 degrees C or higher and 450 degrees C or lower.

### Supplementary Note 17

The semiconductor device manufacturing method of any one of Supplementary Note 1 to 16, wherein a surface of the underlayer is TiN or TaN.

### Supplementary Note 18

The semiconductor device manufacturing method of any one of Supplementary Note 1 to 17, wherein the metal-containing layers include at least one of Ru, Co, or Cu.

### Supplementary Note 19

The semiconductor device manufacturing method of any one of Supplementary Note 1 to 18, wherein in d), gases of a first monomer and a second monomer are supplied into the chamber, and the organic film is embedded in the groove by vapor deposition polymerization of the first monomer and the second monomer.

### Supplementary Note 20

The semiconductor device manufacturing method of Supplementary Note 19,

wherein the first monomer is an isocyanate,

wherein the second monomer is an amine, and

wherein the organic film contains urea bonds.

### Supplementary Note 21

A semiconductor device manufacturing system, includes:

a first processing apparatus;

a second processing apparatus;

a third processing apparatus;

a fourth processing apparatus; and

a control device configured to control the first processing apparatus, the second processing apparatus, the third processing apparatus, and the fourth processing apparatus,

wherein the control device performs:
a) preparing, in a chamber of the first processing apparatus, a substrate having a pattern including a plurality of metal-containing layers formed on an underlayer and a dielectric layer formed on each of the metal-containing layers;
b) modifying sidewalls of the metal-containing layers by supplying a modifying gas into the chamber;
c) generating plasma from a first processing gas including a carbon-containing gas in the chamber, and forming a graphene film on the sidewalls of the metal-containing layers by using the generated plasma;
d) embedding, by using the second processing apparatus, a thermally decomposable organic film in a groove formed by adjacent metal-containing layers;
e) forming, by using the third processing apparatus, a sealing film on the organic film embedded in the groove; and
f) forming, by using the fourth processing apparatus, an air gap between the groove and the sealing film, by heating the substrate to thermally decompose the organic film and detaching the organic film via the sealing film.

According to the present disclosure in some embodiments, it is possible to manufacture a semiconductor device with reduced signal delay.

While certain embodiments have been described, these embodiments have been presented by way of example only, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A semiconductor device manufacturing method, comprising:
a) preparing, in a chamber, a substrate having a pattern including a plurality of metal-containing layers formed on an underlayer and a dielectric layer formed on each of the metal-containing layers;
b) modifying sidewalls of the metal-containing layers by supplying a modifying gas into the chamber;
c) generating plasma from a first processing gas including a carbon-containing gas in the chamber, and forming a graphene film on the sidewalls of the metal-containing layers by using the generated plasma;
d) embedding a thermally decomposable organic film in a groove formed by adjacent metal-containing layers;
e) forming a sealing film on the organic film embedded in the groove; and
f) forming an air gap between the groove and the sealing film, by heating the substrate to thermally decompose the organic film and detaching the organic film via the sealing film.

2. The semiconductor device manufacturing method of claim 1, further comprising g) irradiating plasma into the groove via the sealing film after the air gap is formed in f).

3. The semiconductor device manufacturing method of claim 2, wherein in g), plasma generated from a second processing gas, which is an oxygen-containing gas, is irradiated into the groove via the sealing film.

4. The semiconductor device manufacturing method of claim 2, wherein in g), plasma generated from a third processing gas, which is an oxygen-free gas, is irradiated into the groove via the sealing film.

5. The semiconductor device manufacturing method of claim 4, wherein the third processing gas includes at least one of a rare gas, N₂ gas, or H₂ gas.

6. The semiconductor device manufacturing method of claim 1, further comprising, between d) and e), h) removing the organic film formed on the dielectric layer.

7. The semiconductor device manufacturing method of claim 1, wherein a thickness of the sealing film is 1.6 nm or more and 2.0 nm or less.

8. The semiconductor device manufacturing method of claim 1, wherein the sealing film is a silicon oxide film or a silicon nitride film.

9. The semiconductor device manufacturing method of claim 1, wherein the modifying gas includes an inert gas and a hydrogen-containing gas.

10. The semiconductor device manufacturing method of claim 9, wherein a flow rate ratio of the inert gas to the hydrogen-containing gas is within a range of 200:2 to 50:50.

11. The semiconductor device manufacturing method of claim 9, wherein the inert gas includes at least one of He gas, Ar gas, or N₂ gas.

12. The semiconductor device manufacturing method of claim 9, wherein the hydrogen-containing gas includes at least one of H₂ gas or NH₃ gas.

13. The semiconductor device manufacturing method of claim 1, wherein a temperature of the substrate in c) is 250 degrees C or higher and 550 degrees C or lower.

14. The semiconductor device manufacturing method of claim 1, wherein a temperature of the substrate in d) is 40 degrees C or higher and 150 degrees C or lower.

15. The semiconductor device manufacturing method of claim 1, wherein a temperature of the substrate in e) is 20 degrees C or higher and 100 degrees C or lower.

16. The semiconductor device manufacturing method of claim 1, wherein a temperature of the substrate in f) is 350 degrees C or higher and 450 degrees C or lower.

17. The semiconductor device manufacturing method of claim 1, wherein a surface of the underlayer is TiN or TaN.

18. The semiconductor device manufacturing method of claim 1, wherein the metal-containing layers include at least one of Ru, Co, or Cu.

19. The semiconductor device manufacturing method of claim 1, wherein in d), gases of a first monomer and a second monomer are supplied into the chamber, and the organic film is embedded in the groove by vapor deposition polymerization of the first monomer and the second monomer.

20. The semiconductor device manufacturing method of claim 19,
wherein the first monomer is an isocyanate,
wherein the second monomer is an amine, and
wherein the organic film contains urea bonds.

21. A semiconductor device manufacturing system, comprising:
a first processing apparatus;
a second processing apparatus;
a third processing apparatus;
a fourth processing apparatus; and
a control device configured to control the first processing apparatus, the second processing apparatus, the third processing apparatus, and the fourth processing apparatus,
wherein the control device performs:
a) preparing, in a chamber of the first processing apparatus, a substrate having a pattern including a plurality of metal-containing layers formed on an underlayer and a dielectric layer formed on each of the metal-containing layers;
b) modifying sidewalls of the metal-containing layers by supplying a modifying gas into the chamber;
c) generating plasma from a first processing gas including a carbon-containing gas in the chamber, and forming a graphene film on the sidewalls of the metal-containing layers by using the generated plasma;
d) embedding, by using the second processing apparatus, a thermally decomposable organic film in a groove formed by adjacent metal-containing layers;
e) forming, by using the third processing apparatus, a sealing film on the organic film embedded in the groove; and
f) forming, by using the fourth processing apparatus, an air gap between the groove and the sealing film, by heating the substrate to thermally decompose the organic film and detaching the organic film via the sealing film.
